(19) United States
(12) Patent Application Publication
(10) Pub. No.: US 2006/0286463 A1
(43) Pub. Date: Dec. 21, 2006

(54) Manufacturing method of display device

(75) Inventor: Jeong-Ye Choi, Hwaseong-si (KR)

Correspondence Address: PATENT LAW GROUP LLP, 2635 NORTH FIRST STREET, SUITE 223, SAN JOSE, CA, 95134, US

(73) Assignee: Samsung Electronics Co. LTD.

(21) Appl. No.: 11/413,721

(22) Filed: Apr. 27, 2006

(30) Foreign Application Priority Data
Jun. 16, 2005 (KR) 10-2005-0051760

(51) Int. Cl. G03F 1/00; C09K 19/00

(52) U.S. Cl. 430/7; 430/20

(57) ABSTRACT

A manufacturing method of a display device is provided, which includes applying first electric charges on a surface of a printing drum to form an electric charge film, patterning the electric charge film to form an electric charge film pattern, applying development material having second electric charges to the electric charge film pattern to form a printing pattern, and adhering the printing pattern to a substrate to form a patterned film of the display device. In one embodiment, the printing pattern is a color filter pattern and the patterned film is color filters of the display device.

### RELATED APPLICATION

This application claims priority from Korean Paten Application No. 10-2005-0051760 filed on Jun. 16, 2005, the content of which is incorporated by reference herein in its entirety.

### BACKGROUND OF THE INVENTION

(a) Field of the Invention

The present invention relates to a manufacturing method of a display device.

(b) Description of Related Art

Liquid crystal displays (LCDs) are one type of flat panel displays which have been widely used, and they include two panels provided with field generating electrodes of pixel electrodes and common electrodes, respectively, and a liquid crystal (LC) layer interposed therebetween. Additionally, the LCD includes a sealant for preventing the LC layer from leaking and spacers for maintaining a constant gap between the two panels.

For color display, the LCD includes color filters representing one of primary colors such as red, green, and blue colors formed on one of the panels. The color filters are formed by a photolithography process requiring exposing, developing, and etching. However, as a size of the LCD becomes larger, difficulty of alignment increases and manufacturing equipment of the color filters also becomes larger, which increases the manufacturing cost.

### SUMMARY OF THE INVENTION

A motivation of the present invention is to solve the problems of conventional techniques.

In one aspect of the present invention, a manufacturing method of a display device includes applying first electric charges to a surface of a printing drum to form an electric charge film, patterning the electric charge film to form an electric charge film pattern, applying development material having second electric charges to the electric charge film pattern to form a printing pattern, and adhering the printing pattern to a substrate to form a patterned film of the display device.

The first electric charges may be opposite to those of the second electric charges, and they may be positive electric charges. The electric charge film pattern formation may include irradiating light from a light source to the electric charge film, and the light source may be a light emitting diode.

In one embodiment, the printing pattern is a color filter pattern and the patterned film is color filters of the display device. The color filter forming method may further include hardening the color filters adhered on the substrate to strongly fix them to the surface of the substrate. The color filter fixation may include blowing hot air.

Finally, the manufacturing method may also include removing the development material and the first electric charges remaining on the surface of the printing drum.

### BRIEF DESCRIPTION OF THE DRAWINGS

The present invention will become more apparent by describing preferred embodiments thereof in detail with reference to the accompanying drawings, in which:

FIG. 1 is a schematic of an image forming apparatus according to an embodiment of the present invention;

FIG. 2 is a layout view of a TFT array panel of an LCD according to the embodiments of the present invention;

FIG. 3 is a layout view of a color filter panel of an LCD according to embodiments of the present invention;

FIG. 4 is a layout view of the LCD having the TFT array panel and the color filter panel shown in FIGS. 2 and 3 according to the embodiments of the present invention;

FIG. 5 is a sectional view of the LCD shown in FIG. 4 taken along the line V-V;

FIG. 6 shows sectional views of the LCD shown in FIG. 4 taken along the lines VI-VI;

FIG. 7 is an equivalent circuit diagram of a pixel of an OLED display according to an embodiment of the present invention;

FIG. 8 is a schematic plan view of a display panel for an OLED according to an embodiment of the present invention;

FIG. 9 is a section view of the display panel shown in FIG. 8 taken along the line IX-IX; and

FIG. 10 is a section view of the display panel shown in FIG. 8 taken along the line X-X.

### DETAILED DESCRIPTION OF EMBODIMENTS

The present invention will be described more fully hereinafter with reference to the accompanying drawings, in which preferred embodiments of the invention are shown. This invention may, however, be embodied in many different forms and should not be construed as limited to the embodiments set forth herein.

In the drawings, the thickness of layers and regions are exaggerated for clarity. Like numerals refer to like elements throughout. It will be understood that when an element such as a layer, film, region, substrate, or panel is referred to as being “on” another element, it can be directly on the other element or intervening elements may also be present. In contrast, when an element is referred to as being “directly on” another element, there are no intervening elements present.

Manufacturing methods of a color filter panel for an LCD using an image forming apparatus according to embodiments of the present invention will now be described with reference to drawings.

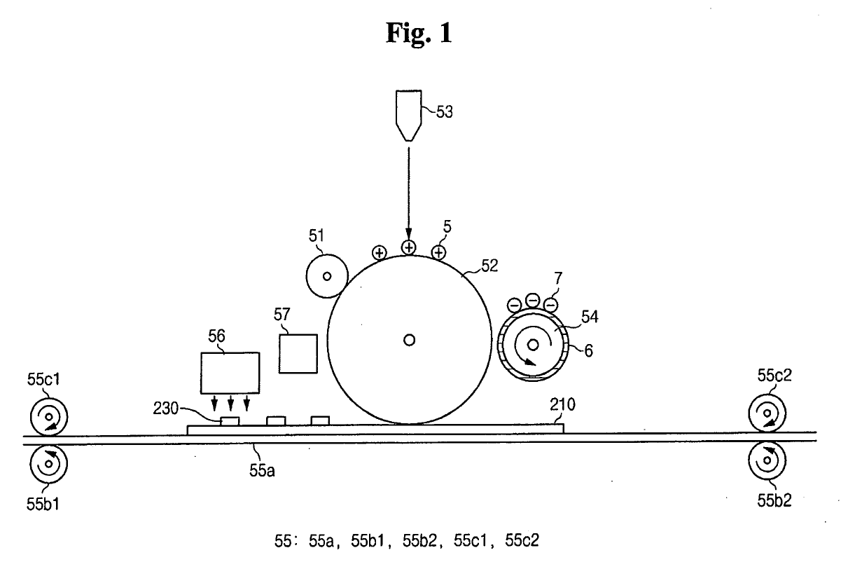

An image forming apparatus according to an embodiment of the present invention will be described with reference to FIG. 1.

FIG. 1 is a schematic of an image forming apparatus according to an embodiment of the present invention.

Referring to FIG. 1, an image forming apparatus according to an embodiment of the present invention includes a printing drum 52 that is capable of being rotated, an electrification roller 51, a toner cartridge 54, a cleansing portion 57, a light source 53, a substrate supplying portion 55, and a color filter fixing portion 56.

The electrification roller 51 contacts a surface of the printing drum 52, to enable the roller to rotate together with the printing drum 52, and uniformly charges the surface of the printing drum 52 with positive (+) electric charges 5.

The light source 53 is disposed above the printing drum 52 and includes an optical system (not shown) such as lenses or mirrors, to irradiate light.

The toner cartridge 54 contacts the surface of the printing drum 52, to enable the cartridge 54 to rotate together with the printing drum 52 and supplies a toner 6 to the surface of the printing drum 52. The toner 6 has one of red, green, and blue colors and has negative (−) electric charges 7.

The substrate supplying portion 55 is disposed under the printing drum 52 and includes a supporting plate 55a, a pair of first moving rollers 55b1 and 55b2, and a pair of second moving rollers 55c1 and 55c2.

The supporting plate 55a mounts a substrate 210, on which color filters 230 are formed, and moves forward or backward based on a rotating direction of the first and second moving rollers 55b1, 55b2, 55c1, and 55c2. The substrate 210 may be a transparent substrate made of glass or plastic.

The pair of first moving rollers 55b1 and 55b2 are placed toward the front and rear near a portion on which the substrate 210 is disposed, and they contact a first surface of the supporting plate 55a, for example a lower surface, to rotate in a first direction.

The pair of second moving rollers 55c1 and 55c2 are disposed opposite to the first moving rollers 55b1 and 55b2 with respect to the supporting plate 55a, and they contact a second surface of the supporting plate 55a, for example an upper surface, to rotate in a second direction.

The first direction is opposite to the second direction.

The first moving rollers 55b1 and 55b2 are rotated in a counterclockwise direction and the second moving rollers 55c1 and 55c2 are rotated in a clockwise direction, such that the substrate 210 moves forward, or the first moving rollers 55b1 and 55b2 are rotated in a clockwise direction and the second moving rollers 55c1 and 55c2 are rotated in a counterclockwise direction, such that the substrate 210 moves rearward. However the positions and the rotation direction of the moving rollers 55b1, 55b2, 55c1, and 55c2 may be varied.

The cleansing portion 57 is located lower than the electrification roller 51, and removes the remaining toner 6 and the remaining electric charges 5 and 7.

The color filter fixing portion 56 is positioned at a certain height above the substrate 210 having passed the printing drum 52, and blows high temperature air toward the substrate 210.

Next, an operation of the image forming apparatus will be described in detail.

The substrate 210 is a color filter panel for an LCD, and the image forming apparatus forms a plurality of color filters 230 on the color filter panel 210. When the printing drum 52 is rotated, the roller 51 and the cleansing portion 57 and the toner cartridge 54 rotate together with the printing drum 52.

By the rotation of the electrification roller 51, a surface of the printing drum 52 is uniformly charged with positive (+) electric charges 5, to form the positive electric charge film on the surface of the printing drum 52.

Next, the light source 53 irradiates light to the surface of the printing drum 52. The light is irradiated to the surface of the printing drum 52 through a mask (not shown) which includes light transmitting portions and light blocking portions having predetermined patterns, respectively, such that a desired pattern of the positive electric charges 5 is formed. At this time, the formed positive electric charge pattern is substantially similar to a desired pattern of the color filters 230. The light source 53 may be at least one LED (light emitting diode).

Alternatively, the positive electric charge pattern may be formed by using laser beams. In this case, the positive electric charge pattern may be formed by adjusting the irradiation interval of the laser beams.

Next, by rotating the printing drum 52 in the clockwise direction, the surface of the printing drum 52 contacts the toner cartridge 54 with the toner 6, thereby applying the development material 6 to the surface of the printing drum 52 to form a printing pattern. In the present illustration, the printing pattern is a color filter pattern.

The surface of the printing drum 52 applied with the color filter pattern then contacts the surface of the substrate 210 and the toner 6 is applied to the surface of the substrate 210 as the supporting plate 55a moves forward by rotation of the first and second moving rollers 55b1, 55b2, 55c1, and 55c2, such that the color filter pattern made of the toner 6 is applied as the color filters 230.

At this time, since the portions on which the toner 6 is applied are already charged with the positive electric charges 5, the toner 6 having the negative electric charges 7 is applied only to the positive electric charge pattern, to form the desired color filter pattern.

That is, the development material 6 is applied on only the positive electric charge pattern based on a static electricity effect between the positive electric charges 5 and the negative electric charge 7.

When the substrate 210 is placed under the color filter fixing portion 56 by the forward movement of the substrate 210, the applied color filters 230 are harden by hot air from the color filter fixing portion 56, so that the applied color filters 230 are strongly adhered or affixed to the surface of the substrate 210. Alternatively, the color filters 230 may be adhered on the surface of the substrate 210 by pressure. At this case, the color filter fixing portion 56 may be a pressure apparatus that contacts surfaces of the color filters 230.

The toner 6 and the electric charges 5 and 7 remaining on the surface of the printing drum 52 are removed by the cleansing portion 57. The cleansing portion 57 may include a brush, a light source, a squeegee, etc.

As described above, when the color filters 230 are formed using the image forming apparatus according to an embodiment of the present invention, a separate photolithography process is not necessary. Thereby, a manufacturing process of an LCD becomes simplified. In addition, since the amount of color filter material eliminated by the photolithography process decreases, the manufacturing cost decreases.

The image forming apparatus according to an embodiment of the present invention forms the color filters 230 for an LCD. However, in other embodiments, the image forming apparatus of the present invention may be used to form other films for an LCD such as a light blocking member or other films for other display devices. In one embodiment, the image forming apparatus of the present invention is used to form the organic light emitting members of an OLED. When the image forming apparatus is used to form the light blocking member, the toner 6 has a black color. When the image forming apparatus is used to form the organic light emitting members of an OLED, the toner 6 is an organic material emitting the primary color of lights, such as red, green and blue lights

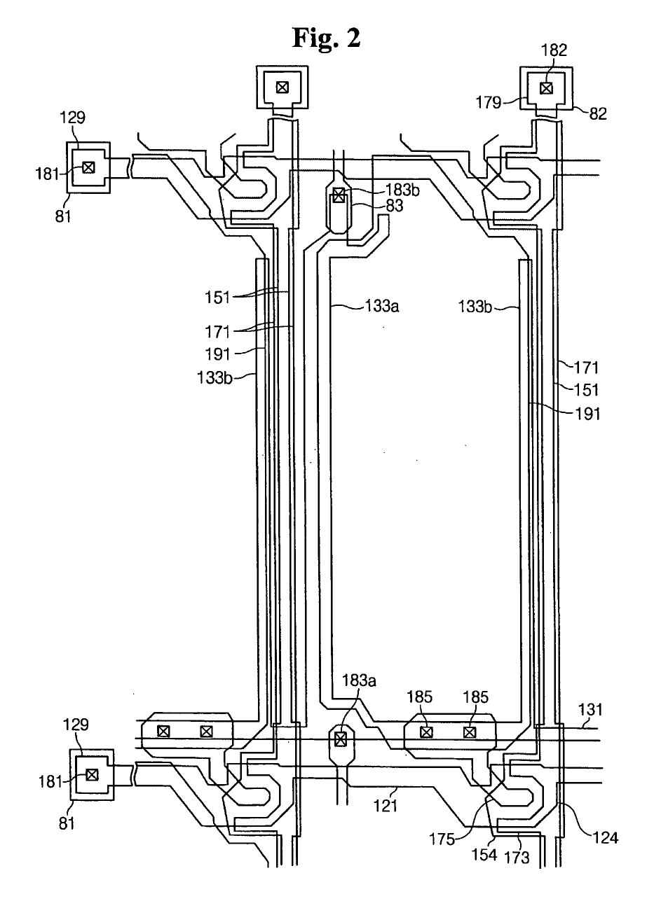

Next, an LCD including color filters formed by the image forming apparatus according to an embodiment of the present invention will be described with reference to FIGS. 2 to 6.

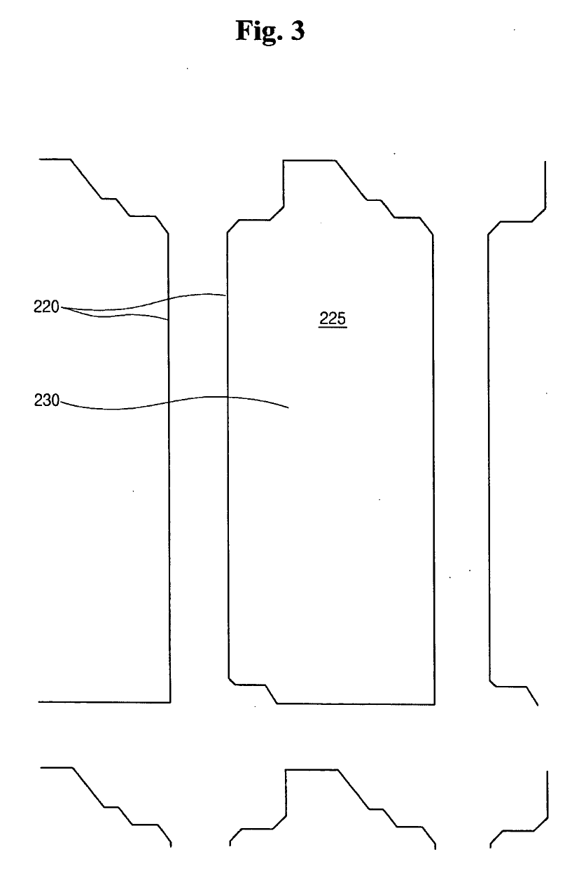

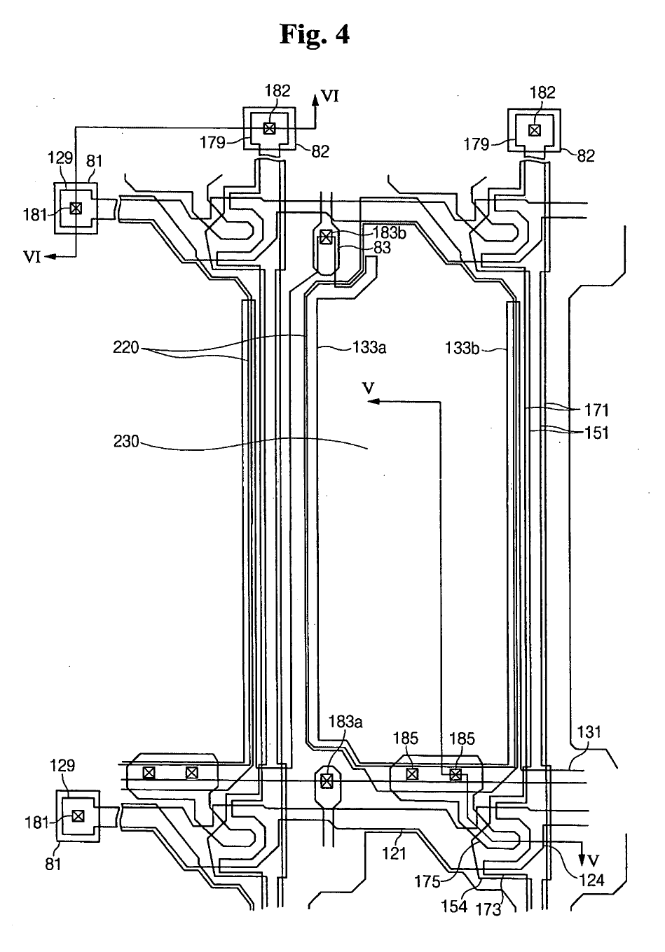

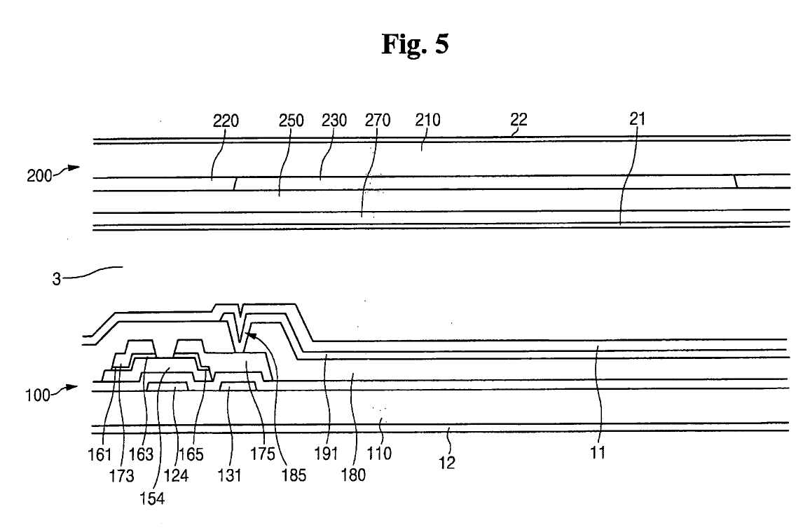

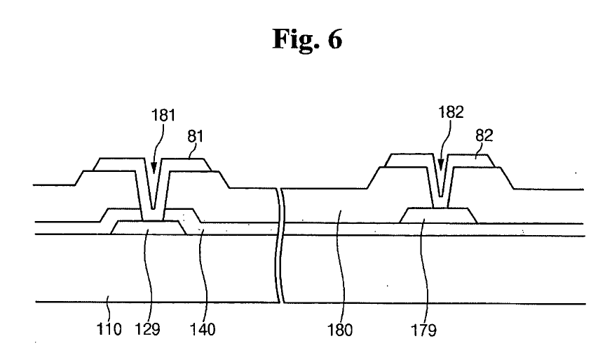

FIG. 2 is a layout view of a TFT array panel of an LCD according to the embodiments of the present invention, and FIG. 3 is a layout view of a color filter panel of an LCD according to embodiments of the present invention. FIG. 4 is a layout view of the LCD having the TFT array panel and the color filter panel shown in FIGS. 2 and 3 according to the embodiments of the present invention, FIG. 5 is a sectional view of the LCD shown in FIG. 4 taken along the line V-V, and FIG. 6 shows sectional views of the LCD shown in FIG. 4 taken along the lines VI-VI.

An LCD according to an embodiment of the present invention includes a TFT array panel 100, a color filter panel 200 opposite to the TFT array panel 100, and an LC layer 3 having LC molecules that is disposed between the two panels.

First, a TFT array panel 100 according to an embodiment of the present invention will be described in detail with reference to FIGS. 2 and 4 to 6.

A plurality of gate lines 121 and a plurality of storage electrode lines 131 are formed on an insulating substrate 110 made of a material such as transparent glass or plastic.

The gate lines 121 transmit gate signals, and they extend substantially in a transverse direction. Each of the gate lines 121 includes a plurality of gate electrodes 124 projecting downward and having a large area for contact with another layer or an external driving circuit. A gate driving circuit (not shown) for generating the gate signals may be mounted on a flexible printed circuit (FPC) film (not shown), which may be attached to the substrate 110, directly mounted on the substrate 110, or integrated onto the substrate 110. The gate lines 121 may extend to be connected to a driving circuit that may be integrated on the substrate 110.

The storage electrode lines 131 are supplied with a predetermined voltage, and each of the storage electrode lines 131 includes a stem extending substantially parallel to the gate lines 121 and a plurality of pairs of storage electrodes 133a and 133b branched from the stems. Each of the storage electrode lines 131 is disposed between two adjacent gate lines 121, and a stem is close to one of the two adjacent gate lines 121. Each of the storage electrodes 133a and 133b has a fixed end portion connected to the stem and a free end portion disposed opposite thereto. The fixed end portion of the storage electrode 133a has a large area, and the free end portion thereof is bifurcated into a linear branch and a curved branch. However, the storage electrode lines 131 may have various shapes and arrangements.

The gate lines 121 and the storage electrode lines 131 are preferably made of an Al-containing metal such as Al and an Al alloy, a Ag-containing metal such as Ag and a Ag alloy, a Cu-containing metal such as Cu and a Cu alloy, a Mo-containing metal such as Mo and a Mo alloy, Cr, Ta, or Ti. However, they may have a multi-layered structure including two conductive films (not shown) having different physical characteristics. One of the two films is preferably made of a low resistivity metal such as an Al-containing metal, a Ag-containing metal, and a Cu-containing metal for reducing signal delay or voltage drop. The other film is preferably made of a material such as a Mo-containing metal, Cr, Ta, or Ti, which have good physical, chemical, and electrical contact characteristics with other materials such as indium tin oxide (ITO) or indium zinc oxide (IZO). Good examples of the combination of the two films are a lower Cr film and an upper Al (alloy) film and a lower Al (alloy) film and an upper Mo (alloy) film. However, the gate lines 121 and the storage electrode lines 131 may be made of various metals or conductors.

The lateral sides of the gate lines 121 and the storage electrode lines 131 are inclined relative to a surface of the substrate 110, and the inclination angle thereof ranges about 30-80 degrees.

A gate insulating layer 140 preferably made of silicon nitride (SiNx) or silicon oxide (SiOx) is formed on the gate lines 121 and the storage electrode lines 131.

A plurality of semiconductor stripes 151 preferably made of hydrogenated amorphous silicon (abbreviated to “a-Si”) or polysilicon are formed on the gate insulating layer 140. The semiconductor stripes 151 extend substantially in the longitudinal direction and become wider near the gate lines 121 and the storage electrode lines 131 such that the semiconductor stripes 151 cover large areas of the gate lines 121 and the storage electrode lines 131. Each of the semiconductor stripes 151 includes a plurality of projections 154 branched out toward the gate electrodes 124.

A plurality of ohmic contact stripes and islands 161 and 165 are formed on the semiconductor stripes 151. The ohmic contact stripes and islands 161 and 165 are preferably made of n+hydrogenated a-Si heavily doped with an N-type impurity such as phosphorous, or they may be made of silicide. Each ohmic contact stripe 161 includes a plurality of projections 163, and the projections 163 and the ohmic contact islands 165 are located in pairs on the projections 154 of the semiconductor stripes 151.

The lateral sides of the semiconductor stripes 151 and the ohmic contacts 161 and 165 are inclined relative to the surface of the substrate 110, and the inclination angles thereof are preferably in a range of about 30-80 degrees.

A plurality of data lines 171 and a plurality of drain electrodes 175 are formed on the ohmic contacts 161 and 165 and the gate insulating layer 140.

The data lines 171 transmit data signals and extend substantially in the longitudinal direction to intersect the gate lines 121. Each data line 171 also intersects the storage electrode lines 131 and runs between adjacent pairs of storage electrodes 133a and 133b. Each data line 171 includes a plurality of source electrodes 173 projecting toward the gate electrodes 124 and being curved like a crescent, and an end portion 179 having a large area for contact with another layer or an external driving circuit. A data driving circuit (not shown) for generating the data signals may be mounted on an FPC film (not shown), which may be attached to the substrate 110, directly mounted on the substrate 110, or integrated onto the substrate 110. The data lines 171 may extend to be connected to a driving circuit that may be integrated on the substrate 110.

The drain electrodes 175 are separated from the data lines 171 and disposed opposite the source electrodes 173 with respect to the gate electrodes 124. Each of the drain electrodes 175 includes a wide end portion and a narrow end portion. The wide end portion overlaps a storage electrode line 131 and the narrow end portion is partly enclosed by a source electrode 173.

A gate electrode 124, a source electrode 173, and a drain electrode 175 along with a projection 154 of a semiconductor stripe 151 form a TFT having a channel formed in the projection 154 disposed between the source electrode 173 and the drain electrode 175.

The data lines 171 and the drain electrodes 175 are preferably made of a refractory metal such as Cr, Mo, Ta, Ti, or alloys thereof. However, they may have a multilayered structure including a refractory metal film (not shown) and a low resistivity film (not shown). Good examples of the multi-layered structure are a double-layered structure including a lower Cr/Mo (alloy) film and an upper Al (alloy) film, and a triple-layered structure of a lower Mo (alloy) film, an intermediate Al (alloy) film, and an upper Mo (alloy) film. However, the data lines 171 and the drain electrodes 175 may be made of various metals or conductors.

The data lines 171 and the drain electrodes 175 have inclined edge profiles, and the inclination angles thereof range about 30-80 degrees.

The ohmic contacts 161 and 165 are interposed only between the underlying semiconductor stripes 151 and the overlying conductors 171 and 175 thereon, and reduce the contact resistance therebetween. Although the semiconductor stripes 151 are narrower than the data lines 171 at most places, the width of the semiconductor stripes 151 becomes large near the gate lines 121 and the storage electrode lines 131 as described above, to smooth the profile of the surface, thereby preventing disconnection of the data lines 171. The semiconductor stripes 151 have almost the same planar shapes as the data lines 171 and the drain electrodes 175 as well as the underlying ohmic contacts 161 and 165. However, the semiconductor stripes 151 include some exposed portions, which are not covered with the data lines 171 and the drain electrodes 175, such as portions located between the source electrodes 173 and the drain electrodes 175.

A passivation layer 180 is formed on the data lines 171, the drain electrodes 175, and the exposed portions of the semiconductor stripes 151. The passivation layer 180 is preferably made of an inorganic or organic insulator and it may have a flat top surface. Examples of the inorganic insulator include silicon nitride and silicon oxide. The organic insulator may have photosensitivity and a dielectric constant of less than about 4.0. The passivation layer 180 may include a lower film of an inorganic insulator and an upper film of an organic insulator such that it takes the excellent insulating characteristics of the organic insulator while preventing the exposed portions of the semiconductor stripes 151 from being damaged with the organic insulator.

The passivation layer 180 has a plurality of contact holes 182 and 185 exposing the end portions 179 of the data lines 171 and the drain electrodes 175, respectively. The passivation layer 180 and the gate insulating layer 140 have a plurality of contact holes 181 exposing end portions 129 of the gate lines 121, a plurality of contact holes 183a exposing portions of the storage electrode lines 131 near the fixed end portions of the storage electrodes 133a, and a plurality of contact holes 183b exposing the linear branches of the free end portions of the storage electrodes 133a.

A plurality of pixel electrodes 191, a plurality of overpasses 83, and a plurality of contact assistants 81 and 82 are formed on the passivation layer 180. They are preferably made of a transparent conductor such as ITO or IZO, or a reflective conductor such as Ag, Al, Cr, or alloys thereof.

The pixel electrodes 191 are physically and electrically connected to the drain electrodes 175 through the contact holes 185 such that the pixel electrodes 191 receive data voltages from the drain electrodes 175. The pixel electrodes 191 supplied with the data voltages generate electric fields in cooperation with a common electrode 270 of the opposing color filter panel 200 supplied with a common voltage, which determine the orientations of liquid crystal molecules (not shown) of a liquid crystal layer 3 disposed between the two panels 100 and 200. A pixel electrode 191 and the common electrode 270 form a capacitor referred to as a “liquid crystal capacitor,” which stores applied voltages after the TFT turns off.

A pixel electrode 191 overlaps a storage electrode line 131 including storage electrodes 133a and 133b. The pixel electrode 191 and a drain electrode 175 connected thereto and the storage electrode line 131 form an additional capacitor referred to as a “storage capacitor,” which enhances the voltage storing capacity of the liquid crystal capacitor.

The contact assistants 81 and 82 are connected to the end portions 129 of the gate lines 121 and the end portions 179 of the data lines 171 through the contact holes 181 and 182, respectively. The contact assistants 81 and 82 protect the end portions 129 and 179 and enhance the adhesion between the end portions 129 and 179 and external devices.

The overpasses 83 cross over the gate lines 121 and they are connected to the exposed portions of the storage electrode lines 131 and the exposed linear branches of the free end portions of the storage electrodes 133a through the contact holes 183a and 183b, respectively, which are disposed opposite each other with respect to the gate lines 121. The storage electrode lines 131 including the storage electrodes 133a and 133b along with the overpasses 83 can be used for repairing defects in the gate lines 121, the data lines 171, or the TFTs.

A description of the color filter panel 200 follows with reference to FIGS. 3 and 5.

A light blocking member 220 referred to as a black matrix for preventing light leakage is formed on an insulating substrate 210 made of a material such as transparent glass or plastic.

The light blocking member 220 has a plurality of openings 225 (FIG. 3) that face the pixel electrodes 191, and it may have substantially the same planar shape as the pixel electrodes 191. Otherwise, the light blocking member 220 may include a plurality of portions facing the gate lines 121 and data lines 171 on the TFT array panel 100 and a plurality of widened portions facing the TFTs on the TFT array panel 100. The light blocking member 220 functions as side walls for sealing ink for color filters 230 therein when the color filter panel is manufactured using the inkjet printing system.

A plurality of color filters 230 are also formed on the substrate 210. The color filters 230 are formed substantially in openings 225 enclosed by the light blocking member 220. Alternatively, the color filters 230 may extend substantially in the longitudinal direction along the pixel electrodes 191. The color filters 230 may represent one of the primary colors such as red, green, and blue colors. The pattern of color filters 230 formed in blocking member 220 is shown in FIG. 3.

An overcoat 250 is formed on the color filters 230 and the light blocking member 220. The overcoat 250 is preferably made of an (organic) insulator and it prevents the color filters 230 from being exposed and provides a flat surface. The overcoat 250 may be omitted.

A common electrode 270 is formed on the overcoat 250. The common electrode 270 is preferably made of a transparent conductive material such as ITO and IZO.

Alignment layers 11 and 21 that may be horizontal or vertical alignment layers are coated on inner surfaces of the panels 100 and 200, and polarizers 12 and 22 are provided on outer surfaces of the panels 100 and 200 so that their polarization axes may cross and one of the polarization axes may be parallel to the gate lines 121. One of the polarizers 12 and 22 may be omitted when the LCD is a reflective LCD.

The LCD may further include at least one retardation film (not shown) for compensating the retardation of the LC layer 3.

The LCD may further include a backlight unit (not shown) for supplying light to the LC layer 3 through the polarizers 12 and 22, the retardation film, and the panels 100 and 200.

Now, a method of manufacturing the TFT array panel shown in FIGS. 2 to 6 according to an embodiment of the present invention will be described.

A metal film is sputtered on an insulating substrate 110 made of a material such as transparent glass or plastic, and is patterned by wet etching or dry etching with a photoresist pattern to form a plurality of gate lines 121 including a plurality of gate electrodes 124 and an end portion 129 and a plurality of storage electrodes 131 having a pair of storage electrodes 133a and 133b.

After sequential deposition of a gate insulating layer 140, an intrinsic a-Si layer, and an extrinsic a-Si layer, the extrinsic a-Si layer and the intrinsic a-Si layer are photo-etched to form a plurality of extrinsic semiconductor stripes 161 not and a plurality of intrinsic semiconductor stripes 151 including a plurality of projections 154 on the gate insulating layer 140. The gate insulating layer 140 has a thickness of about 1500 Å to about 5500 Å, the intrinsic a-Si layer has a thickness of about 500 Å to about 2000 Å, and the extrinsic a-Si layer thickness is about 300 Å to about 600 Å.

A conductive layer is sputtered with a thickness of about 1500 Å to about 3000 Å, and is patterned by etching with a photoresist pattern to form a plurality of data lines 171 including a plurality of source electrodes 173 and end portions 179, and a plurality of drain electrodes 175.

Portions of the extrinsic a-Si layer which are not covered with the data lines 171 and the drain electrodes 175 are removed by etching to complete a plurality of ohmic contact stripes 161 including a plurality of projections 163 and a plurality of ohmic contact islands 165, and to expose portions of the intrinsic semiconductor stripes 151. Oxygen plasma treatment may follow thereafter in order to stabilize the exposed surfaces of the semiconductor stripes 151.

A passivation layer 180 preferably made of positive photosensitive organic materials is deposited on the data lines 171, the drain electrodes 175, and the exposed semiconductor stripes 151.

The passivation layer 180 is exposed to light through a photo mask. The photo mask includes a transparent substrate and an opaque light blocking film, and it is divided into light transmitting areas, light blocking areas, and translucent areas. The light blocking film is not disposed on the light transmitting areas, but it is disposed on the light blocking areas and the translucent areas. The light blocking film exists as a wide area having a width larger than a predetermined value on the light blocking areas, and it exists as a plurality of areas having width or distance smaller than a predetermined value to form slits.

The passivation layer 180 is developed to form a plurality of contact holes 182 and 185 exposing the end portions 179 of the data lines and the drain electrodes 175. The passivation layer 180 is also developed along with the gate insulating layer 140 to form the contact holes 181, 183a, and 183b exposing the end portions 129 of the gate lines 121, and the storage electrodes 133a and 133b of the storage electrode lines 131, respectively.

In a case that the passivation layer 180 is made of negative photosensitive materials, the positions of the light transmitting areas and the light locking areas of the photo mask are changed with each other.

Finally, IZO or ITO with a thickness of about 400 Å to about 500 Å is sputtered and etched to form a plurality of pixel electrodes 191, a plurality of contact assistants 81 and 82 and overpasses 83 on the passivation layer 180, the exposed drain electrodes 175, the end portions 179 of the data lines 171, the end portions 129 of the gate lines 121, and the exposed storage electrode lines 131.

Next, an OLED display using a panel manufactured by the inkjet printing system according to the embodiments of the present invention will be described with reference to accompanying drawings.

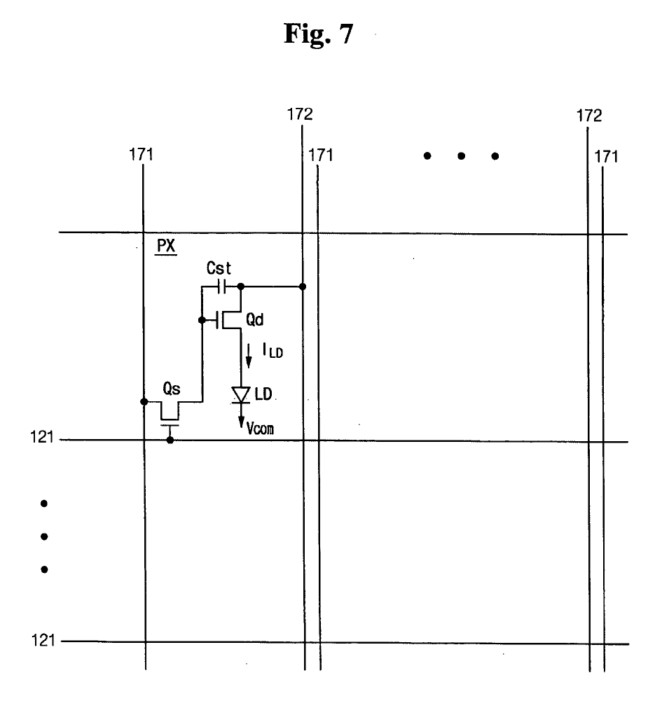

First, an OLED display according to an embodiment of the present invention is described in detail with reference to FIG. 7.

FIG. 7 is an equivalent circuit diagram of a pixel of an OLED display according to an embodiment of the present invention.

Referring to FIG. 7, an OLED display according to an embodiment includes a plurality of signal lines 121, 171, and 172 and a plurality of pixels PX connected thereto and arranged substantially in a matrix.

The signal lines 121, 171, and 172 include a plurality of gate lines 121, a plurality of data lines 171, and a plurality of voltage transmission lines 172.

The gate lines 121 transmitting gate signals (or scanning signals) extend substantially in a row direction and substantially parallel to each other, while the data lines 171 transmitting data signals extend substantially in a column direction and substantially parallel to each other. The voltage transmission lines 172 for transmitting driving voltages extend substantially in a column direction and substantially parallel to each other.

Each pixel includes a switching transistor Qs, a driving transistor Qd, a storage capacitor Cst, and an organic light emitting element LD.

The switching transistor Qs has a control terminal connected to the gate line 121, an input terminal connected to the data line 171, and an output terminal connected to an the driving transistor Qd. The switching transistor Qs transmits the data signal applied to the data line 171 to the driving transistor Qd in response to the scanning signal applied to the scanning line 121.

The driving transistor Qd has a control terminal connected to the switching transistor Qs, an input terminal connected to the voltage transmission line 172, and an output terminal connected to the light emitting element LD. The driving transistor Qd conducts a current having a magnitude defined depending on a voltage applied between the control terminal and the output terminal thereof. The capacitor Cst is connected between the control terminal and the input terminal of the driving transistor Qd. The capacitor Cst charges and maintains the data signal applied to the control terminal of the driving transistor Qd.

The light emitting element LD has an anode connected to the output terminal of the driving transistor Qd and a cathode connected to a common voltage Vcom. The light emitting element LD emits light having an intensity depending on an output current I_{LD} of the driving transistor Qd.

The switching transistor Qs and the driving transistor Qd are N-channel field effect transistors (FETs). At least one of the transistors Qs and Qd may be a P-channel FET. The connections between the transistors Qs and Qd, the capacitor Cst, and the light emitting element LD may be modified.

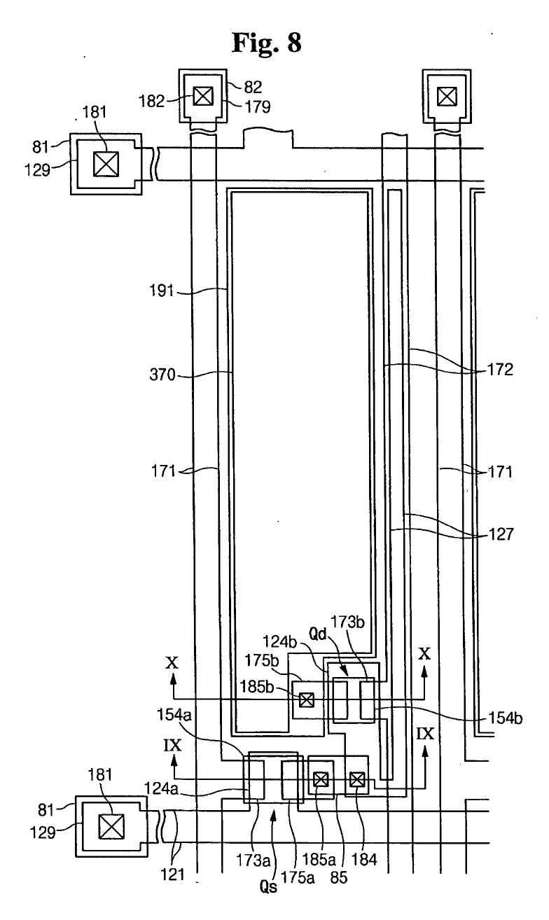

Now, a structure of a display panel for the OLED according to an embodiment of the present invention will be described in detail with reference to FIGS. 8 to 10.

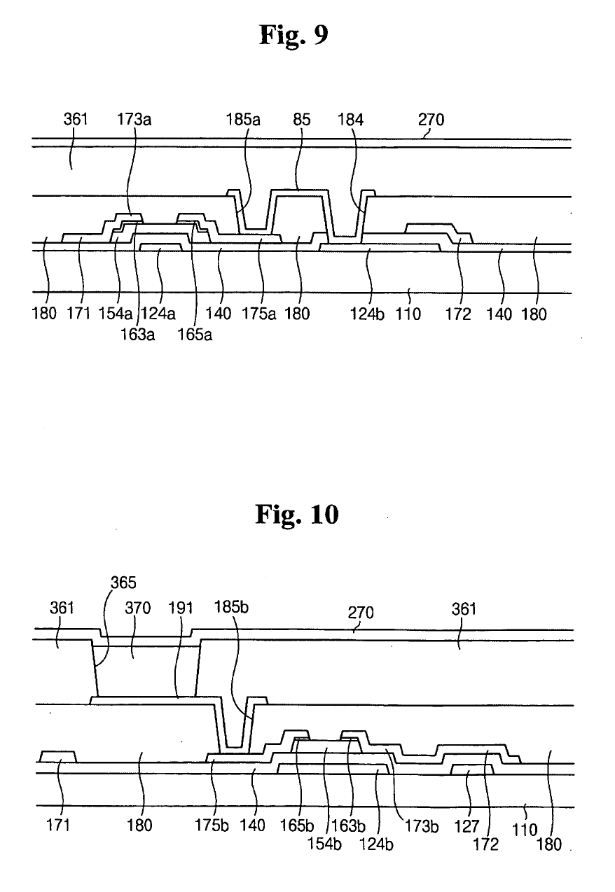

FIG. 8 is a schematic plan view of a display panel for an OLED according to an embodiment of the present invention, FIG. 9 is a section view of the display panel shown in FIG. 8 taken along the line IX-IX, and FIG. 10 is a section view of the display panel shown in FIG. 8 taken along the line X-X.

A plurality of gate conductors that include a plurality of gate lines 121 including first gate electrodes 124a and a plurality of second gate electrodes 124b are formed on an insulating substrate 110 a material such as transparent glass or plastic.

The gate lines 121 transmit gate signals and extend substantially in a transverse direction. Each of the gate lines 121 includes an end portion 129 having a large area for contact with another layer or an external driving circuit. The first gate electrodes 124a projecting upward from the gate lines 121. A gate driving circuit (not shown) for generating the gate signals may be mounted on a flexible printed circuit (FPC) film (not shown), which may be attached to the substrate 110, directly mounted on the substrate 110, or integrated onto the substrate 110. The gate lines 121 may extend to be connected to a driving circuit that may be integrated on the substrate 110.

Each of the second gate electrodes 124b is separated from the gate lines 121 and disposed between two adjacent gate lines 121. The second gate electrode 124b includes a storage electrode 127 that extends downward, turns to the right, and then extends long upward.

The gate conductors 121 and 124b are preferably made of an Al containing metal such as Al and an Al alloy, a Ag containing metal such as Ag and a Ag alloy, a Cu containing metal such as Cu and a Cu alloy, a Mo containing metal such as Mo and a Mo alloy, Cr, Ti or Ta. The gate conductors 121 and 124b may have a multi-layered structure including two films having different physical characteristics. One of the two films is preferably made of a low resistivity metal including an Al-containing metal, a Ag-containing metal, or a Cu-containing metal for reducing signal delay or voltage drop in the gate conductors 121 and 124b. On the other hand, the other film is preferably made of a material such as Cr, Mo, a Mo alloy, Ta, or Ti, which has good physical, chemical, and electrical contact characteristics with other materials such as indium tin oxide (ITO) or indium zinc oxide (IZO). Good examples of the combination of the two films are a lower Cr film and an upper Al (alloy) film and a lower Al (alloy) film and an upper Mo (alloy) film. However, the gate conductors 121 and 124b may be made of various metals or conductors.

The lateral sides of the gate conductors 121 and 124b are inclined relative to a surface of the substrate 110, and the inclination angle thereof ranges about 30-80 degrees.

A gate insulating layer 140 preferably made of silicon nitride (SiNx) or silicon oxide (SiOx) is formed on the gate conductors 121 and 124b.

A plurality of semiconductor islands 154a and 154b preferably made of hydrogenated amorphous silicon (abbreviated to “a-Si”) or polysilicon are formed on the gate insulating layer 140. The semiconductor islands 154a and 154b are disposed on the first and second control electrodes 124a and 124b, respectively.

A plurality of pairs of first and second ohmic contact islands 163a and 163b and a plurality of pairs of third and fourth ohmic contact islands 165a and 165b are formed on the semiconductor islands 154a and 154b, respectively. The ohmic contact islands 163a, 163b, 165a, and 165b are preferably made of n+hydrogenated a-Si heavily doped with an N-type impurity such as phosphorous, or they may be made of silicide.

The first ohmic contact islands 163a and 165a are disposed on the first semiconductor island 154a in pair and the second ohmic contact islands 163b and 165b are disposed on the first semiconductor island 154a in pair.

The lateral sides of the semiconductor islands 154a and 154b and the ohmic contacts 163a, 163b, 165a, and 165b are inclined relative to the surface of the substrate 110, and the inclination angles thereof are preferably in a range of about 30-80 degrees.

A plurality of data conductors including a plurality of data lines 171, a plurality of voltage transmission lines 172, and a plurality of output electrodes 175a and 175b are formed on the ohmic contacts 163a, 163b, 165a, and 165a and the gate insulating layer 140.

The data lines 171 for transmitting data signals extend substantially in the longitudinal direction and intersect the gate lines 121. Each data line 171 may include a plurality of first source electrodes 173a projecting toward the first control electrode 124a and an end portion 179 having a large area for contact with another layer or an external driving circuit. A data driving circuit (not shown) for generating the data signals may be mounted on an FPC film (not shown), which may be attached to the substrate 110, directly mounted on the substrate 110, or integrated into the substrate 110. The data lines 171 may extend to be connected to a driving circuit that may be integrated in the substrate 110.

The voltage transmission lines 172 for transmitting driving voltages for the driving TFT Qd extend substantially in the longitudinal direction and intersect the gate lines 121. Each voltage transmission line 172 includes a plurality of second source electrodes 173b projecting toward the second control electrode 124b. The voltage transmission lines 172 may overlap the electrode electrodes 127 and be connected to each other.

The first drain electrodes 175a and 175b are separated from each other and separated from the data lines 171 and the voltage transmission lines 172.

The first input electrodes 173a are disposed opposite the first output electrodes 175a with respect to the control electrodes 124a and the second input electrodes 173b are also disposed opposite the second output electrodes 175b with respect to the control electrodes 124a.

The data conductors 171, 172, 175a, and 175b are preferably made of a refractory metal such as Cr, Mo, Ta, Ti, or alloys thereof. However, they may have a multilayered structure including a refractory metal film (not shown) and a low resistivity film (not shown). Good examples of the multi-layered structure are a double-layered structure including a lower Cr/Mo (alloy) film and an upper Al (alloy) film and a triple-layered structure of a lower Mo (alloy) film, an intermediate Al (alloy) film, and an upper Mo (alloy) film. However, data conductors 171, 172, 175a, and 175b may be made of various metals or conductors.

Like the gate conductors 121 and 124b, the lateral sides of the data conductors 171, 172, 175a, and 175b are inclined relative to a surface of the substrate 110, and the inclination angle thereof ranges about 30-80 degrees.

The ohmic contacts 163a, 163b, 165a, 165b are interposed only between the underlying semiconductor islands 154a and 154b and the overlying data conductors 171, 172, 175a, and 175b thereon and reduce the contact resistance therebetween. The semiconductor islands 154 and 154b include some exposed portions, which are not covered with the data conductors 171, 172, 175a, and 175b, such as portions located between the input electrodes 173a and 173b and the output electrodes 175a and 175b.

A passivation layer 180 is formed on the data conductors 171, 172, 175a, and 175b and the exposed portions of semiconductor islands 154a and 154b. The passivation layer 180 is preferably made of an inorganic or organic insulator and it may have a flat top surface. Examples of the inorganic insulator include silicon nitride and silicon oxide. The organic insulator may have photosensitivity and a dielectric constant of less than about 4.0. The passivation layer 180 may include a lower film of an inorganic insulator and an upper film of an organic insulator, such that it takes the excellent insulating characteristics of the organic insulator while preventing the exposed portions of the semiconductor islands 154 and 154b from being damaged by the organic insulator.

The passivation layer 180 has a plurality of contact holes 182, 185a, and 185b exposing the end portions 179 of the data lines 171 and the first and second output electrodes 175a and 175b, respectively. The passivation layer 180 and the gate insulating layer 140 have a plurality of contact holes 181 and 184 exposing the end portions 129 of the gate lines 121 and the first input electrodes 124b, respectively.

A plurality of pixel electrodes 191, a plurality of connecting members 85, and a plurality of contact assistants 81 and 82 are formed on the passivation layer 180. They are preferably made of a transparent conductor such as ITO or IZO or a reflective conductor such as Ag, Al, Cr, or alloys thereof.

The pixel electrodes 191 are physically and electrically connected to the second output electrodes 175b through the contact holes 185b. The connecting members 85 are physically and electrically connected to the second control electrodes 124b and the first output electrodes 175a through the contact holes 184 and 185a, respectively.

The contact assistants 81 and 82 are physically and electrically connected to the end portions 129 of the gate lines 121 and the end portions 179 of the data lines 171 through the contact holes 181 and 182, respectively. The contact assistants 81 and 82 protect the end portions 129 and 179 and enhance the adhesion between the end portions 129 and 179 and external devices.

A partition 361 is formed on the passivation layer 180.

The partition 361 surrounds the pixel electrodes 191 like a bank, to define openings 365 to be filled with organic light emitting material. The partition 361 is preferably made of an organic or inorganic insulating material. The partition 361 may be also formed of photoresist including a black pigment to function as a light blocking member, such that a manufacturing procedure is simplified.

A plurality of light emitting members 370 are formed on the pixel electrodes 191 and disposed in the openings 365 defined by the partition 361. The light emitting members 370 are formed using the inkjet printing system according to an embodiment of the present invention. The light emitting members 370 are preferably made of an organic material emitting primary-color lights such as red, green, and blue lights. The red, green, and blue light emitting members 370 are periodically arranged. The OLED represents a desired color by summing the primary colors from the light emitting members 370 in space. The image forming apparatus of FIG. 1 can be applied to form the light emitting members 370 by using an organic light emitting material emitting primary color lights as toner 6. The printing pattern formed on the printing drum is thus a light emitting member pattern.

The organic light emitting member 370 may have a multilayered structure. The organic light emitting member 370 includes an emitting layer (not shown) for emitting light and auxiliary layers (not shown) for improving the efficiency of light emission of the emitting layer. The auxiliary layers include an electron transport layer (not shown) and a hole transport layer (not shown) for improving the balance of the electrons and holes, and an electron injecting layer (not shown) and a hole injecting layer (not shown) for improving the injection of the electrons and holes.

A common electrode 270 is formed on the light emitting members 370. The common electrode 270 is supplied with the common voltage Vcom. The common electrode 270 may preferably be made of reflective conductors such as Al, Ca, Ba, and Mg or alloys thereof or transparent conductors such as ITO or IZO.

In the above-described OLED, a first gate electrode 124a connected to the gate line 121, a first input electrode 173a connected to the data line 171, and a first output electrode 175a along with a first semiconductor island 154a form a switching TFT Qs having a channel formed in the semiconductor island 154a disposed between the input electrode 173a and the second output electrode 175a. A second gate electrode 124b connected to the first output electrode 175a, a second input electrode 173b connected to the voltage transmission line 172, and a second output electrode 175b along with a second semiconductor island 154b form a driving TFT Qd having a channel formed in the semiconductor island 154b disposed between the second input electrode 173b and the second output electrode 175b. The pixel electrodes 191, the organic light emitting members 370, and the common electrode 270 form an organic light emitting elements LD. The pixel electrode 191 may be an anode terminal and the common electrode 270 may be a cathode terminal. On the contrary, the pixel electrode 191 may be a cathode terminal and the common electrode 270 may be an anode terminal. Furthermore, a storage electrode 127 and a voltage transmission line 172 overlapped with each other form a storage capacitor Cst.

The OLEDs emit light upward or downward with respect to the substrate 110 to represent the images.

An opaque pixel electrode and a transparent common electrode are used in OLEDs of a top emission type for representing the images upward with respect to the substrate 110. A transparent pixel electrode and a transparent common electrode are used in OLEDs of a bottom emission type for representing the images downward with respect to the substrate 110.

Meanwhile, when the semiconductor islands 154a and 154b are made of polysilicon, the OLED includes intrinsic regions (not shown) disposed opposite to the control electrodes 124a and 124b, respectively, and the extrinsic regions (not shown) disposed on the both of each intrinsic region. The extrinsic regions are electrically connected to the input electrodes 173a and 173b and the output electrodes 175a and 175b, and the ohmic contacts 163a, 163b, 165a, and 165b may be omitted.

The control electrodes 124a and 124b may be disposed on the semiconductors 154a and 154b. In this case, the gate insulating layer 140 is disposed between the semiconductors 154a 154b and the control electrodes 124a and 124b. At this time, the data conductors 171, 172, 175a, and 175b are disposed on the gate insulating layer 140 and are electrically connected to the semiconductors 154a and 154b through contact holes (not shown) formed on the gate insulating layer 140. Alternatively, the data conductors 171, 172, 175a, and 175b are disposed under the semiconductor islands 154a and 154b and may be connected to the overlaying semiconductor islands 154a and 154b.

The embodiment of the present invention has been described with respect to OLEDs including the semiconductors made of a-Si, however, the present may be adopted to OLEDs including semiconductors made of polysilicon.

As described above, the color filters are formed using the image forming apparatus according to an embodiment of the present invention, and thereby a separate photolithography process is not necessary. Accordingly, a manufacturing process of an LCD becomes simple and manufacturing costs decreases.

The color filters may be formed on a flexile substrate made of plastic instead of glass, and the image forming apparatus according to the present invention may be adopted to display devices having the flexible substrate.

Furthermore, as described above, the image forming apparatus of the present invention can be applied to form other films for any type of display devices. For instance, the image forming apparatus can be applied to form the light emitting members of an OLED.

While the present invention has been described in detail with reference to the preferred embodiments, it is to be understood that the invention is not limited to the disclosed embodiments, but, on the contrary, is intended to cover various modifications and equivalent arrangements included within the spirit and scope of the appended claims.

What is claimed is:

1. A manufacturing method of a display device comprising:
applying first electric charges on a surface of a printing drum to form an electric charge film;
patterning the electric charge film to form an electric charge film pattern;
applying development material having second electric charges to the electric charge film pattern to form a printing pattern; and
adhering the printing pattern to a substrate to form a patterned film of the display device.

2. The method of claim 1, wherein the first electric charges are opposite to the second electric charges.

3. The method of claim 1, wherein the first electric charges are positive electric charges.

4. The method of claim 1, wherein the electric charge film pattern formation comprises irradiating light from a light source to the electric charge film.

5. The method of claim 4, wherein the light source comprises a light emitting diode.

6. The method of claim 1, wherein the printing pattern comprises a color filter pattern and the patterned film comprises color filters of the display device.

7. The method of claim 6, further comprising hardening the color filters adhered on the substrate to affix the color filters to the surface of the substrate.

8. The method of claim 7, wherein hardening the color filters adhered on the substrate to affix the color filters to the surface of the substrate by blowing hot air onto the color filter pattern.

9. The method of claim 1, further comprising removing the development material and the first electric charges remaining on the surface of the printing drum.

10. The method of claim 1, wherein the printing pattern comprises an organic light emitting member pattern and the patterned film comprises an organic light emitting material emitting primary color lights of the display device.

11. The method of claim 10, further comprising hardening the organic light emitting material adhered on the substrate to affix the organic light emitting material to the surface of the substrate.
